(19) United States
(12) Patent Application Publication
(10) Pub. No.: US 2008/0145976 A1
(43) Pub. Date: Jun. 19, 2008

(54) Packaging of Micro Devices

(76) Inventors: Conor O'Mahony, County Kerry (IE); Martin Hill, County Cork (IE)

Correspondence Address: JACOBSON HOLMAN PLLC, 400 SEVENTH STREET N.W., SUITE 600, WASHINGTON, DC, 20004, US

(21) Appl. No.: 11/795,865

(22) PCT Filed: Jan. 24, 2006
(86) PCT No.: PCT/IE2006/000004

§ 371 Date: Jul. 24, 2007

(30) Foreign Application Priority Data
Jan. 24, 2005 (IE) 2005/0035

(51) Int. Cl. H01L 21/58

(52) U.S. Cl. 438/126; 257/E21.505

(57) ABSTRACT

A silicon wafer is used as a substrate (1). A thin layer of metal is deposited and etched to form device metallisation (3), including electrodes and bondpads. A passivation layer (4) of silicon nitride is patterned to open access points to the metal. A lower sacrificial layer (5) is formed from polyimide and is patterned (at 5(a) and 5(b)) to open anchor regions for a device and for bridges that will define lateral etch channels for package evacuation. Structural materials that form a MEMS device (6) and bridges (13) are then deposited and patterned. The bridges (13) are patterned simultaneously with the device 6 on the lower sacrificial layer (5). An upper sacrificial layer (7) is then deposited over the device (6) and the lower sacrificial layer (5) and is patterned to open anchor regions (8) for an encapsulation layer (10). Both sacrificial layers are then simultaneously removed in an oxygen plasma ash through lateral etc channels (15). This step leaves a hollow and empty shell, inside which the MEMS device (6) is present. The device (6) is free to move after sacrificial layer removal and has clearance both above and below. The etch channels (15) are sealed by a sealant (40) applied over the encapsulant layer.

### FIELD OF THE INVENTION

The invention relates to packaging of structures such as microelectromechanical systems (MEMS) devices.

### PRIOR ART DISCUSSION

Advances in microelectromechanical systems (MEMS) have been rapid since the early 1970's, and micromachined components are now commonly found in uses such as accelerometers and low-cost medical applications. Radio-frequency components for mobile communications are also the subject of intensive research; these include switches, HF frequency filters, phase shifters, inductors, varactors and micromechanical resonators.

A major barrier to the commercialisation of these devices is the cost and complexity of packaging. Unlike IC's, the unprotected movable component of a MEMS device is unlikely to survive standard packaging steps such as wafer dicing, assembly, wire bonding, and encapsulation processes. Furthermore, the final package must allow the device to move freely, yet provide protection from contaminants and rough handling. A hermetic environment is often desired by applications such as resonators or switches, as the presence of water vapour or other contaminants can cause failure, while package pressure plays an important part in determining the dynamic characteristics of the component (resonant frequency, switching speed).

Current solutions include high-temperature encapsulation, wafer-to-wafer bonding or substrate transfer processes. These include eutectic and fusion bonding, intermediate layer soldering, and CVD bonding. However, there are a number of problems associated with these techniques—
Many bonding processes require high temperatures in order to achieve a good seal. High temperature levels are not compatible with many process materials or MEMS structures—high temperatures may cause thermal mismatch and result in device bowing or distortion.
Many methods of packaging these components also require specialist equipment or techniques that may not be commonly found within a conventional IC foundry or process.
Some techniques require separate encapsulation of each individual device, a process that is expensive and time-consuming.
Most wafer-to-wafer bonding or capping schemes require large areas of ‘dead’ wafer space where the bond is to be formed. This is a very real cost in terms of the number of devices per wafer that can be fabricated.
Outgassing from organic compounds using during the wafer-to-wafer bonding process may affect the hermeticity of the package cavity and have a detrimental effect on device performance.

Another approach is on the basis of fabricating the device and package as part of the same process flow, using the same surface micromachining technology. This is often referred to as an ‘integrated’, ‘zero-level’, or ‘wafer-level’ package. U.S. Pat. No. 6,465,280, assigned to Analog Devices, describes an approach in which a MEMS device (for example, a switch, filter, resonator, or accelerometer) is built on a lower sacrificial layer. Without removing the lower sacrificial layer, a upper sacrificial layer is deposited over both the device and lower sacrificial layer. A capping layer is then deposited over both sacrificial layers and anchored to the substrate through anchor points cut in these sacrificial layers. The sacrificial layers are then removed through holes etched on top of the capping layer, leaving a freestanding device within a hollow cavity or shell. To further protect the device, the holes in the capping layer are plugged using a sealing layer that ensures a hermetic environment.

There are several problems with this approach. In particular, sealing material may be deposited through the etch holes and this may affect the operation of the device. Furthermore, because of the aspect ratio of these etch holes, they may be difficult to seal in the first place. Because of these problems, techniques to release the sacrificial layers through lateral (horizontal) pipes or channels have been developed.

Such a technique has been described by Lin et al (J. Microelectromechanical Systems 7, pp. 286-294, 1998). This packaging method is based on encasing the device within a double sacrificial layer of PSG oxide, over which is deposited a shell of silicon nitride. The sacrificial layer is then removed through small etch channels using concentrated hydrofluoric acid (HF), the wafer is rinsed and dried, and the shell is sealed. The wafer is then diced in the usual way and the chips are packaged using standard IC packaging techniques. However, the high temperatures and aggressive liquid etchants used in the fabrication process mean that this technique is unsuitable for the packaging of many metallic devices.

US Patent Application 2003/0153116 (L. R. Carley et al) describes a low-temperature method in which a layer of metal is patterned on an insulated substrate to form bondpads, electrodes and associated metallisation. This is passivated by a layer such as silicon nitride. A planar sacrificial layer such as photoresist is then deposited and etched to open anchor points for the structure. The structure is formed from a metal such as aluminium or titanium on top of this lower sacrificial layer. A upper sacrificial layer is then deposited over both the device and lower sacrificial layer.

Holes are then etched through both sacrificial layers to the substrate around the device and an encapsulation layer is deposited. This forms a lid or shell that is anchored to the substrate via pillars that are defined by the holes in the sacrificial layers. The sacrificial layers are then removed using an oxygen plasma, which etches the sacrificial layers through the holes that remain between the encapsulation layer pillars. These holes are then filled using a blanket sealing layer to encapsulate the device in a hermetic environment.

A problem with this approach is the height of the holes that remain between the encapsulation layer pillars. The height of the holes or channels is equal to the sum of the thicknesses of the sacrificial layers. In surface micromachining, these thicknesses are usually of the order of 1-5 μm, and the channel height is therefore up to 10 μm.

It follows that in order to seal these high channels, a very thick sealing layer is needed, which may cause problems, in particular:
thick sealing layers of silicon oxide or similar are prone to cracking.
stress mismatch may occur between the thick sealing layer and the thinner encapsulation shell, causing delamination or cracking of the encapsulation layer.
standard processing methods may be unable to pattern such a thick layer.
the height of the channel means that it is far easier for sealing material to enter the cavity via the etch channels before closure of the channel occurs.

The invention addresses this problem.

### SUMMARY OF THE INVENTION

According to the invention, there is provided a method of packaging a device comprising the steps of:
providing a substrate,
depositing and patterning a lower sacrificial layer;
constructing a structure on the lower sacrificial layer;
depositing and patterning an upper sacrificial layer over the structure and the lower sacrificial layer;
depositing and patterning an encapsulation layer over the structure and both sacrificial layers; and
etching the sacrificial layers beneath the encapsulation layer by delivering etchant through lateral etch channels between the encapsulation layer and the substrate, said channels having a lower height than the combined thickness of the sacrificial layers.

In one embodiment, the lateral etch channels have a height of only the lower sacrificial layer.

In one embodiment, the structure forms bridges on the lower sacrificial layer and the lateral etch channels are between the bridges and the substrate.

In one embodiment, the structure forms a device, and removal of the sacrificial layers evacuates space above and below the device.

In another embodiment, the bridges are constructed simultaneously with the device.

In one embodiment, the encapsulation layer is conformal with the bridges.

In a further embodiment, the encapsulation layer is anchored on top of the bridges.

In one embodiment, the bridges form, in a circumferential direction around the device, a pattern of being on the substrate and being spaced-apart from the substrate to provide the channels.

In one embodiment, the sacrificial layers are formed from an organic material.

In one embodiment, the sacrificial layers are formed from polyimide or photoresist.

In another embodiment, the sacrificial layers are removed by dry oxygen plasma etching.

In one embodiment, the method comprises the further step of depositing a pad of material on the substrate under the location of at least one bridge to reduce channel height.

In one embodiment, the pad is applied by metallisation.

In one embodiment, said metallisation is simultaneous with metallisation of the substrate underneath the lower sacrificial layer.

In one embodiment, the method comprises the further step of partially etching the lower sacrificial layer to reduce channel height.

In one embodiment, the method further includes the step of depositing a sealing layer over the encapsulation layer, whereby the sealing layer blocks the lateral etch channels, forming a sealed cavity beneath the encapsulation layer.

In one embodiment, the sealing material is selectively etched in order to provide access to electrical contact pads.

In one embodiment, the step of patterning the sealing material uses liquid etchants.

### DETAILED DESCRIPTION OF THE INVENTION

### Brief Description of the Drawings

The invention will be more clearly understood from the following description of some embodiments thereof, given by way of example only with reference to the accompanying drawings in which:—

FIGS. 1 to 10 are cross-sectional diagrams showing a packaging process of the invention;

FIG. 11 is a diagram showing a final packaged device and the key to shadings used in the preceding drawings;

FIG. 12 is an SEM image of a fabricated and sealed micro-cavity;

FIG. 13 is a plan view photograph of a fabricated and sealed micro-cavity, illustrating the structure within;

FIG. 14 is an electromechanical result showing the performance characteristics of a packaged structure; and

FIGS. 15 and 16 are cross-sectional diagrams illustrating alternative embodiments.

### DESCRIPTION OF THE EMBODIMENTS

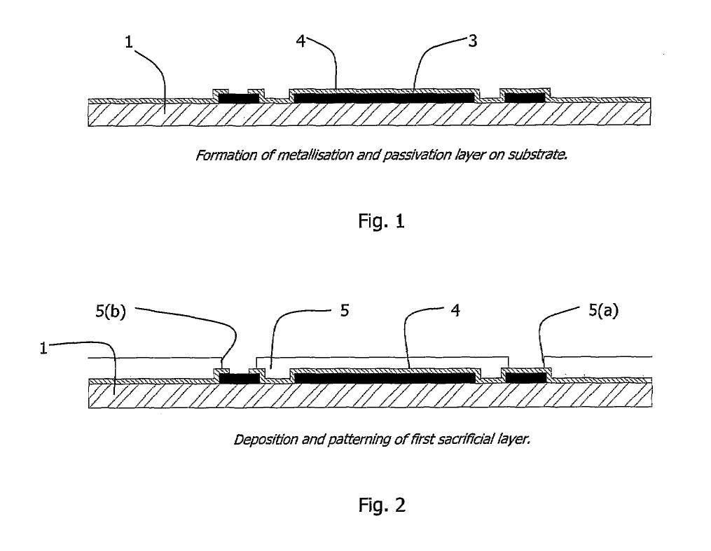

Referring to FIG. 1, in a packaging process a silicon wafer is used as the substrate 1. However, depending on the device, the substrate material may alternatively be of another material such as glass, silicon, quartz, or SOI. The substrate may have been previously worked upon, for example, CMOS circuitry may have been fabricated on it.

The substrate is electrically isolated by incorporating a layer of silicon oxide. Over this, a thin layer of metal is deposited and etched to form device metallisation 3, including electrodes and bondpads. This layer may interface with underlying CMOS circuitry via contact holes opened in the underlying isolation layer. A passivation layer 4 of silicon nitride (or alternatively oxide or similar) is patterned to open access points to the metal.

Referring to FIG. 2, a lower sacrificial layer 5 is formed from polyimide and is patterned at 5(a) and 5(b) to open anchor regions for a device and for bridges that will define the lateral etch channels for package evacuation.

The lower sacrificial layer may alternatively be of an organic layer such as photoresist which is sensitive to a dry oxygen plasma gas.

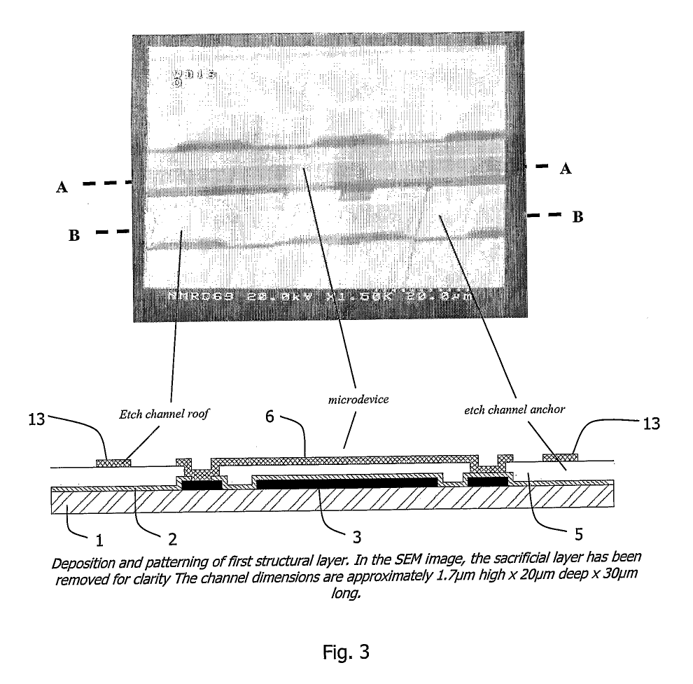

Referring to FIG. 3 a structure, in this embodiment structural materials that form a MEMS device 6 and bridges 13 are then deposited and patterned. The device 6 may comprise a resonator, a switch, a frequency filter, or an accelerometer for example. These have been formed from metal (titanium, aluminium) and composite (aluminium-oxide, titanium-oxide) materials. Monolayer or multilayer devices may be formed. For simplicity, this description will assume a monolayer device.

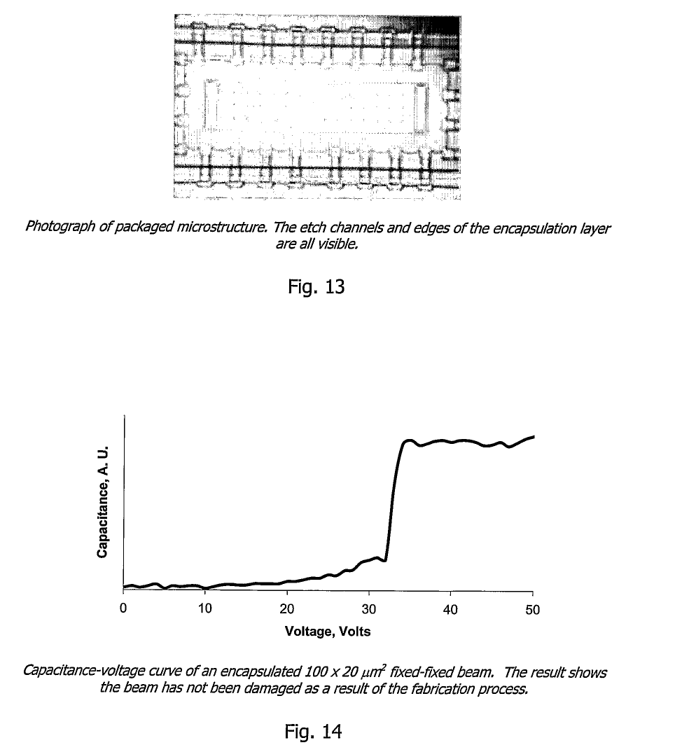

FIG. 3 also illustrates the cross-section which is used in these diagrams (along the line A-A). The diagram part of FIG. 3 includes bridges because these exist laterally in the direction of the line A-A beyond the extent of the SEM of FIG. 3. This is shown in FIG. 13.

An important aspect of this step is that the bridges 13 are patterned simultaneously with the device 6 on the lower sacrificial layer 5. However, it is possible to deposit and pattern the device and bridges separately and from different materials.

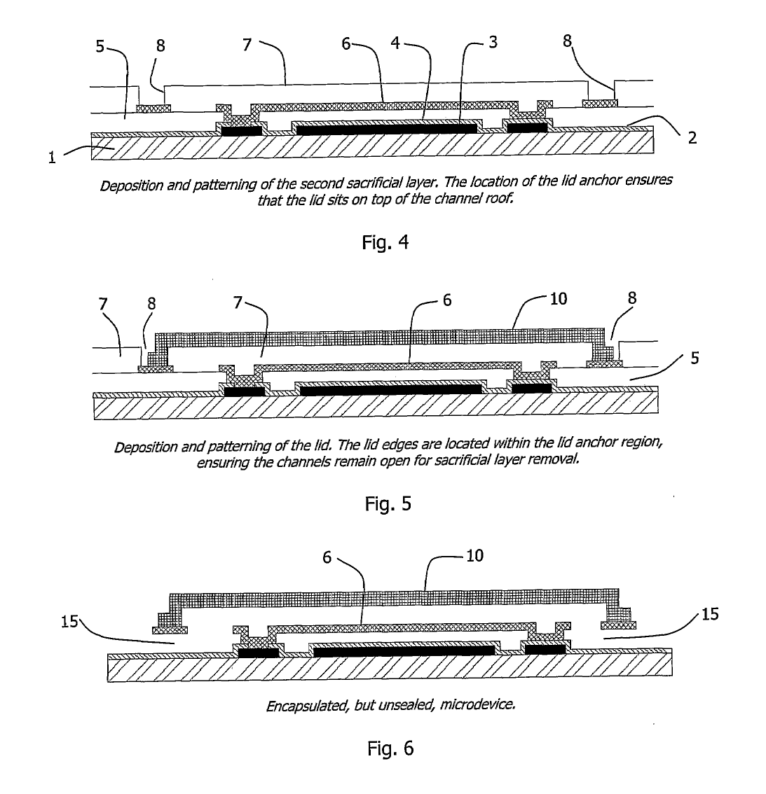

Referring to FIG. 4, an upper sacrificial layer 7 is then deposited over the device 6 and the lower sacrificial layer 5 and patterned to open anchor regions 8 for an encapsulation layer. The boundaries of the anchor regions lie over and between the bridges 13, ensuring that the encapsulation layer will be anchored on the material from which the bridges are constructed. It is desirable that the upper sacrificial layer is of the same material as the lower one.

Referring to FIG. 5, there is deposition of an encapsulation layer 10. This is patterned to extend over all of the MEMS device 6 area, but not beyond the anchor regions 8. This ensures that etch channels remain open to allow simultaneous removal of both sacrificial layers. The encapsulation layer 10 may be formed from any low-temperature material but in this embodiment silicon oxide is preferred.

As shown in FIG. 6, both sacrificial layers are then simultaneously removed in an oxygen plasma ash. This dry-release method does not cause problems with stiction, and the aggressive etchants used in some prior processes (e.g. hydrofluoric acid) are not required. This diagram shows the lateral etch channels 15.

This step leaves a hollow and empty shell, inside which the MEMS device 6 is present. The device 6 is free to move after sacrificial layer removal and has clearance both above and below.

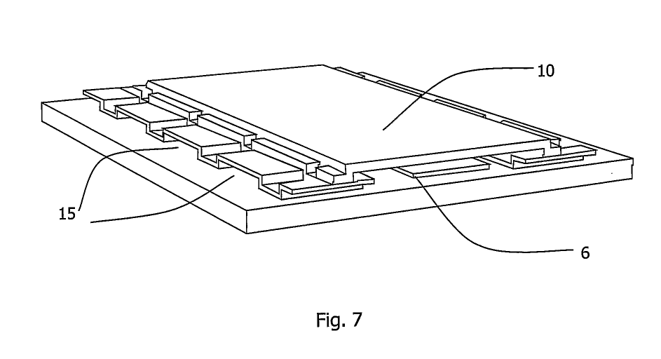

FIG. 7 shows a three-dimensional image of a microcavity, showing the channels 15 and the device 6 within the cavity under the encapsulation layer 10. This shows how the encapsulation layer is interconnected with the bridges away from the A-A cross-section.

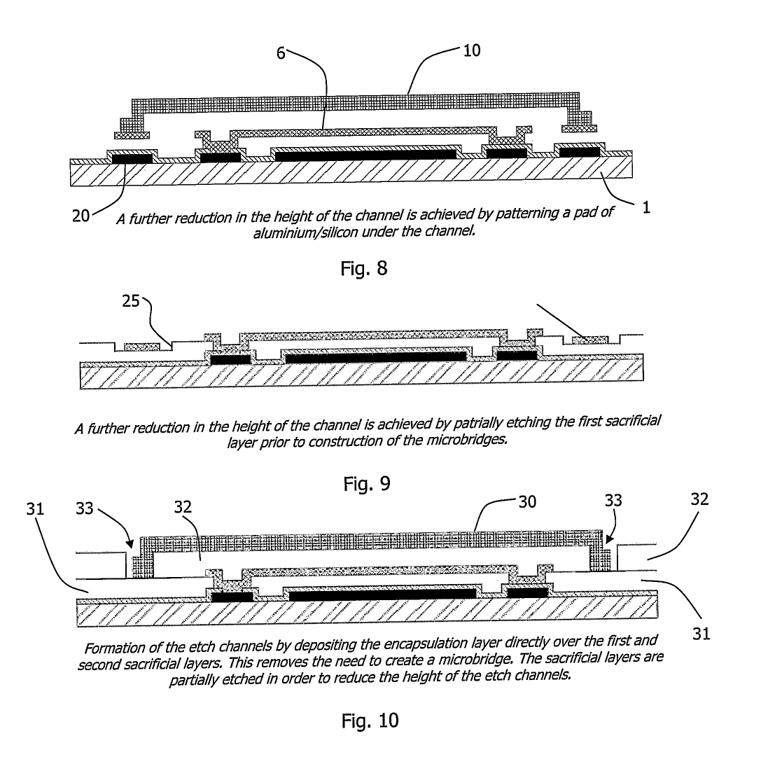

In a further embodiment the height of the channels is reduced still further, FIG. 8. The metallisation layer may be patterned to allow a pad 20 of the metal to remain under the channels. The height of the channel is now given by the thickness of the lower sacrificial layer minus the height of the metallisation layer. For this process, this is about 1.5 μm, a reduction of 60%-75% on the channel height created using a process of the prior art. The additional reduction in the channel height further reduces the thickness of sealing material required to close the channel. The pad may alternatively be formed from any other low-temperature material.

In a further embodiment the height of the channels is reduced still further, FIG. 9. The lower sacrificial layer may be partially etched at 25 to create a shallow trench in the sacrificial layer surface where the bridge is to be defined. The height of the channel is now given by the thickness of the lower sacrificial layer minus the height of the trench. This may be combined with the embodiment described in the previous paragraph to reduce the height of the channel still further.

Referring to FIG. 10, in a further embodiment an encapsulation layer 30 may be deposited directly over lower and upper sacrificial layers 31 and 32 in order to form lateral etch channels without needing to create a bridge. The sacrificial layers are partially etched at 33 in order to reduce the height of the etch channels and avoid some of the problems described in the introduction.

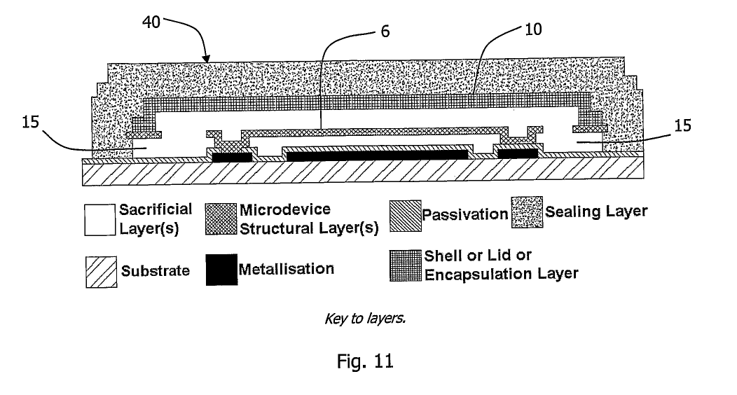

Referring to FIG. 11, the etch channels are then blocked by deposition of a suitably thick layer of sealing material 40, resulting in the creation of a sealed cavity. Results show that 3-4 μm silicon oxide layer is sufficient to seal the channels, although any other low-temperature material may be used. This diagram also shows the shading key used for the other diagrams.

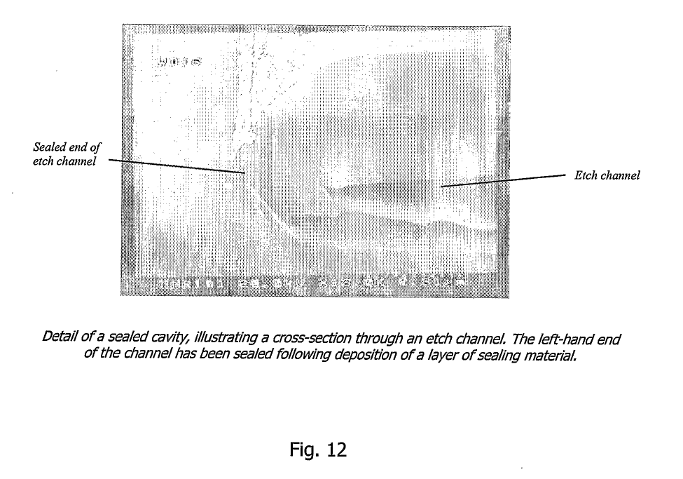

FIG. 12 shows an SEM image of a fabricated and sealed microcavity showing a sealed channel. FIG. 13 shows a photograph of a micropackage after sealing. The structure, encapsulation layer and lateral etch channels are all visible.

In order to allow electrical access to the device, the sealing layer is patterned by etching the oxide in a solution of 50:50:50 solution of acetic acid, ammonium fluoride and water in order to remove the sealing material from over the bondpads or electrical contact points. The wafer may subsequently be diced and packaged using standard IC packaging techniques.

FIG. 14 is an electromechanical result of a fully packaged structure. The capacitance-voltage curve shows that the MEMS device exhibits a clearly-defined instability point at 34V. This means that the structure is free to move inside the cavity and has not been damaged by the packaging process.

It will be appreciated that the channel height depends on the thickness of the lower sacrificial layer only, or indeed less as shown in FIGS. 8 and 9. This represents a significant reduction and considerably reduces the thickness of sealing layer required and alleviates some of the prior art problems. It will also be appreciated that the structure in one step defines the series of bridges encircling, but spaced apart from, the device to be encapsulated, and also forms the device. These bridges define the etch channels.

Because the upper sacrificial layer is patterned over and between the bridges to form an anchor region for the encapsulating layer, the latter may be deposited and patterned in such a way that it does not extend beyond the outer edges of the bridges. The encapsulating shell is therefore anchored to the top of the structural layer that defines these channels.

As described above with reference to FIG. 8, the height of the channel may be reduced still further by extending the metallisation layer underneath the channels. This means that the channel height is now equal to the thickness of the lower sacrificial layer minus the metallisation layer thickness. Also, as described above with reference to FIG. 9, the channel height may also be reduced by partially etching the lower sacrificial layer in those regions where the channels are to be defined. This means that the channel height is now equal to the thickness of the lower sacrificial layer minus the depth of the partial etch.

The sacrificial layers are very effectively removed using a dry oxygen plasma etch to leave a freestanding device within an open package. The etch channels are subsequently sealed at low pressure using a low-temperature PECVD oxide or similar material. A thickness of approximately 3-4 μm has been shown to achieve channel sealing.

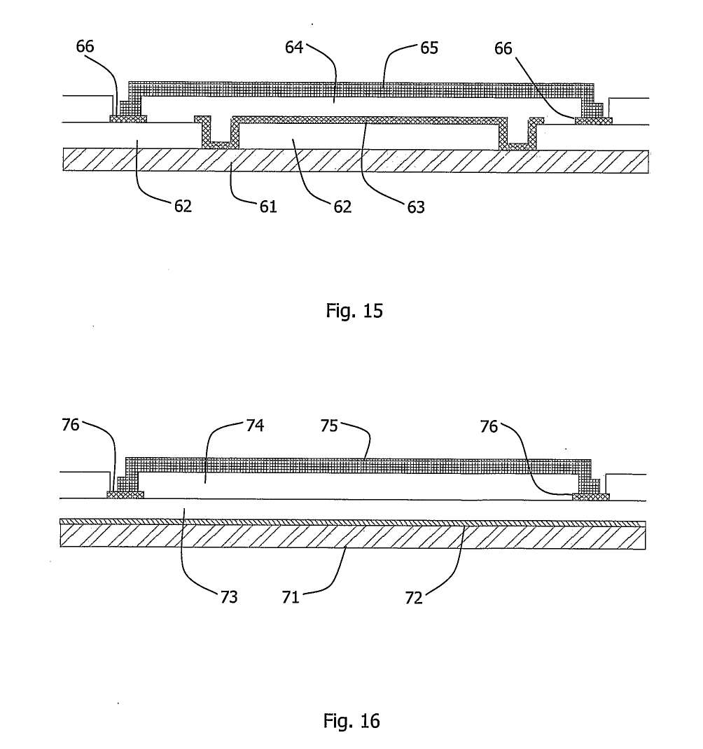

Referring to FIG. 15, in another embodiment there is a substrate 61, a lower sacrificial layer 62, a device 63, an upper sacrificial layer 64, an encapsulation layer 65, and bridges 66. There is therefore no metallisation and consequently no passivation. This arrangement is suitable where the substrate incorporates suitable conductors.

Referring to FIG. 16 there is a substrate 71, passivation 72, a lower sacrificial layer 73, an upper sacrificial layer 74, an encapsulation layer 75, and bridges 76. In this embodiment, therefore, there is no device. This is instead incorporated in the substrate.

Many advantages of the process will be apparent. Because no high-temperature materials or steps are involved, the process offers a wafer-level packaging solution at low temperatures. The device and package are totally integrated; all process steps are carried out using standard IC processing technology and because the components may be batch fabricated, the potential for low-cost applications is obvious. No aggressive etchants (such as acids) are used during fabrication. This means that a wide range of metals can be used in the process. The method of sacrificial layer removal means that sealing material is not deposited inside the cavity because (a) the etch takes place from the side, instead of from the top, and (b) the lateral length of the channels can be made sufficiently long to make deposition of material inside the cavity highly improbable. However, channel width can be made large in order to facilitate easy and quick removal of the sacrificial material. Because the polyimide is removed in a dry oxygen plasma, problems with stiction do not arise. Considerably less wafer space is needed for fabrication of the device package.

It is believed that the invention represents a significant improvement on the prior art. By defining an etch channel in this manner:—
In the first instance, the height of the lateral etch channel is reduced by more than 50%, and may be reduced still further.
The height of the channel is determined by the thickness of the lower sacrificial layer only. In this embodiment, this is usually 1-2 μm thick—high enough to allow easy removal of sacrificial material, low enough to seal without difficulty.
The thickness of sealing material required is substantially reduced. In this process, the required thickness drops from approximately 8 μm to 3 μm, or even below. This avoids possible problems with stress mismatch and lithography that may arise with thick materials in surface micromachining.
The lower channel height reduces the possibility of sealing material entering the cavity before channel closure is achieved.
No extra non-standard process steps or materials are needed.
Because the entire periphery of the lid is anchored on the material that forms the bridges, (instead of partial anchoring at the pillars only), it is a substantially stronger design than that of the prior art.

The invention is not limited to the embodiments described but may be varied in construction and detail.

1-19. (canceled)

20. A method of packaging a device comprising the steps of:
providing a substrate,
depositing and patterning a lower sacrificial layer;
constructing a structure on the lower sacrificial layer;
depositing and patterning an upper sacrificial layer over the structure and the lower sacrificial layer;
depositing and patterning an encapsulation layer over the structure and both sacrificial layers; and
etching the sacrificial layers beneath the encapsulation layer by delivering etchant through lateral etch channels between the encapsulation layer and the substrate, said channels having a lower height than the combined thickness of the sacrificial layers.

21. The method as claimed in claim 20, wherein the lateral etch channels have a height of only the lower sacrificial layer.

22. The method as claimed in claim 20, wherein the structure forms bridges on the lower sacrificial layer and the lateral etch channels are between the bridges and the substrate.

23. The method as claimed in claim 20, wherein the structure forms a device, and removal of the sacrificial layers evacuates space above and below the device.

24. The method as claimed in claim 23, wherein the bridges are constructed simultaneously with the device.

25. The method as claimed in claim 20, wherein the structure forms bridges on the lower sacrificial layer and the lateral etch channels are between the bridges and the substrate; and wherein the encapsulation layer is conformal with the bridges.

26. The method as claimed in claim 20, wherein the structure forms bridges on the lower sacrificial layer and the lateral etch channels are between the bridges and the substrate; and wherein the encapsulation layer is anchored on top of the bridges.

27. The method as claimed in claim 23, wherein the bridges form, in a circumferential direction around the device, a pattern of being on the substrate and being spaced-apart from the substrate to provide the channels.

28. The method as claimed in claim 20, wherein the sacrificial layers are formed from an organic material.

29. The method as claimed in claim 20, wherein the sacrificial layers are formed from polyimide or photo-resist.

30. The method as claimed in claim 20, wherein the sacrificial layers are removed by dry oxygen plasma etching.

31. The method as claimed in claim 20, wherein the structure forms bridges on the lower sacrificial layer and the lateral etch channels are between the bridges and the substrate; and wherein the method comprises the further step of depositing a pad of material on the substrate under the location of at least one bridge to reduce channel height.

32. The method as claimed in claim 31, wherein the pad is applied by metallisation.

33. The method as claimed in claim 31, wherein the pad is applied by metallization, and wherein said metallisation is simultaneous with metallisation of the substrate underneath the lower sacrificial layer.

34. The method as claimed in claim 20, comprising the further step of partially etching the lower sacrificial layer to reduce channel height.

35. The method as claimed in claim 20, further including the step of depositing a sealing layer over the encapsulation layer, whereby the sealing layer blocks the lateral etch channels forming a sealed cavity beneath the encapsulation layer.

36. The method as claimed in claim 35, where the sealing material is selectively etched in order to provide access to electrical contact pads.

37. The method as claimed in claim 35, where the sealing material is selectively etched in order to provide access to electrical contact pads; and wherein the step of patterning the sealing material uses liquid etchants.

38. The packaged device whenever produced by a method as claimed in claim 20.
